(19) United States
(12) Patent Application Publication
(10) Pub. No.: US 2008/0142928 A1
(43) Pub. Date: Jun. 19, 2008

(54) Semiconductor component with through-vias

(76) Inventors: Arkalgud Sitaram, Cedar Park, TX (US); Heinz Hoenigschmid, Poecking (DE)

Correspondence Address: SLATER & MATSIL LLP, 17950 PRESTON ROAD, SUITE 1000, DALLAS, TX, 75252, US

(21) Appl. No.: 11/640,040

(22) Filed: Dec. 15, 2006

(51) Int. Cl. H01L 21/50; H01L 23/48

(52) U.S. Cl. 257/621; 257/777; 438/109; 257/E23.011; 257/E21.499

(57) ABSTRACT

A semiconductor device includes a semiconductor substrate having an upper surface and a lower surface opposed to the upper surface. Integrated circuitry is formed at the upper surface of the semiconductor substrate. A plurality of active through-vias are electrically coupled to the integrated circuitry and extend from the upper surface to the lower surface of the semiconductor substrate. In addition, a plurality of other through-vias extend from the upper surface to the lower surface of the semiconductor substrate and are electrically isolated from any integrated circuitry in the substrate.

### TECHNICAL FIELD

This invention relates generally to interconnected electronic components and in specific embodiments to a method of stacking integrated circuits.

### BACKGROUND

One of the goals in the fabrication of electronic components is to minimize the size of various components. For example, it is desirable that hand held devices such as cellular telephones and personal digital assistants (PDAs) be as small as possible. To achieve this goal, the semiconductor circuits that are included within the devices should be as small as possible. One way of making these circuits smaller is to stack the chips that carry the circuits.

A number of ways of interconnecting the chips within the stack are known. For example, bond pads formed at the surface of each chip can be wire-bonded, either to a common substrate or to other chips in the stack. Another example is a so-called micro-bump 3D package, where each chip includes a number of micro-bumps that are routed to a circuit board, e.g., along an outer edge of the chip.

Yet another way of interconnecting chips within the stack is to use through-vias. Through-vias extend through the substrate thereby electrically interconnecting circuits on various chips. Through-via interconnections can provide advantages in terms of interconnect density compared to other technologies. While there is, in theory, no limit as to the number of chips that can be stacked, the ability to remove heat from inside the stack can limit the number of chips as a practical matter.

### SUMMARY OF THE INVENTION

In one embodiment, a semiconductor device includes a semiconductor substrate having an upper surface and a lower surface opposed to the upper surface. Integrated circuitry is formed at the upper surface of the semiconductor substrate. A plurality of active through-vias are electrically coupled to the integrated circuitry and extend from the upper surface to the lower surface of the semiconductor substrate. In addition, a plurality of other through-vias extend from the upper surface to the lower surface of the semiconductor substrate and are electrically isolated from any integrated circuitry in the substrate.

The details of one or more embodiments of the invention are set forth in the accompanying drawings and the description below. Other features, objects, and advantages of the invention will be apparent from the description and drawings, and from the claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a plan view of a first chip of the present invention;

FIG. 2 is a diagrammatic view of a stack of chips;

FIG. 3 is a plan view of another embodiment of the present invention;

FIG. 4 is a plan view of another embodiment of the present invention; and

FIG. 5 is a flowchart describing the fabrication of a semiconductor chip.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely stacked memory devices. The invention may also be applied, however, to other components such as logic devices, analog or mixed signal chips or non-semiconductor components such as MEMS and optical components.

One goal of the invention is to provide a deep via protocol to connect the chips in a 3D stack together. Implementation of such a protocol can become very complicated if the chips are different from each other. As an example, this can happen when DRAM, flash and logic chips are stacked together.

One approach to solve this problem would be to use controller chips that link the different chips together on the system board. One disadvantage of this approach is that the chips take up two-dimensional space on the system board. This disadvantage can be avoided by using a three-dimensional approach. For example, if a single supplier provides all of the chips, the interconnections can be coordinated. Unfortunately, this goal is difficult to implement when certain companies produce only certain types of chips. Even if a single supplier is found, the system manufacturer lacks flexibility in choosing its vendors.

Standards organizations provide uniformity amongst products produced by various companies in an industry. This uniformity assures the interoperability of components manufactured by different sources. One example of a standards organization is JEDEC, which is the semiconductor engineering standardization body of the Electronic Industries Alliance (EIA), a trade association that represents the electronics industry. JEDEC has issued widely used standards for device interfaces in a number of areas including computer memory. Other standards are adopted by other organizations such as the Institute of Electrical and Electronics Engineers (IEEE).

On occasion standards will exist even without the sanction of a formal body. Such de facto standards can come about when companies begin producing components that have consistent characteristics. For example, a single company may have a very large market share of a product and, as a result, that company's designs become the standard. As another example, a large customer may set specifications for its vendors to follow. In any of these cases, the components produced by different entities will have common properties.

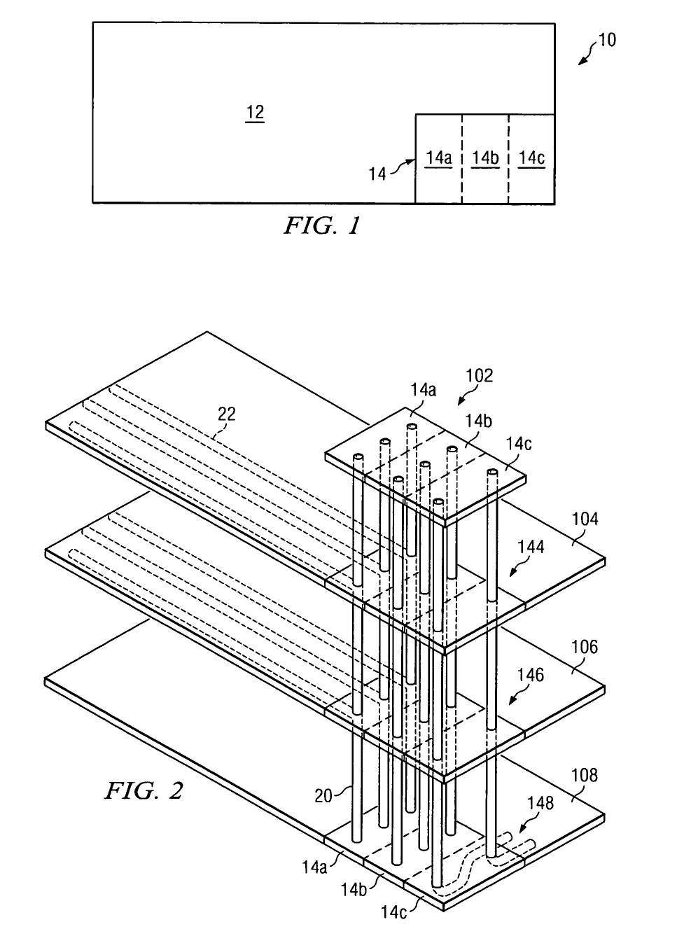

The present invention includes a number of embodiments. In certain embodiments, specific areas, e.g., control areas, are reserved within each chip in a stack of chips. These chips are electrically interconnected by through-vias, e.g., interconnects that extend from an upper surface to a lower surface of the chip. Each control area is dedicated to a different chip type, e.g., DRAM, SRAM, flash. An example of this embodiment is shown in FIG. 1.

Referring now to FIG. 1, a semiconductor chip (die) 10 is illustrated in a simple diagrammatic view. The chip 10 includes functional region 12, where the integrated circuitry that performs the function of the chip is included. For example, if chip 10 is a logic chip, the transistors that form the logic circuits are provided in functional region 12. Similarly, if chip 10 is a memory chip, the memory cells and peripheral circuits are provided in function region 12.

Control region 14 is divided into a number of sections 14a, 14b, 14c (generically 14x). Each section is dedicated to a certain chip-type, e.g., DRAM, SRAM, logic, or whatever other kind of chip is needed. Through-vias (not shown, see e.g., vias 20 in FIG. 2 or vias 20 and 24 in FIG. 4) can be located within the sections 14x. A controller can then be coupled to each of a number of different chips through different parts of the control area. The controller can be one of the chips in the stack or a component outside the stack, e.g., coupled through a circuit board.

FIG. 2 illustrates a stacked configuration that includes four chips 102, 104, 106 and 108. In this particular example, chip 102 is a controller, chips 104 and 106 are a first type of chip and chip 108 is a second type of chip. As shown in the figure, control areas 144, 146 and 148 of the chips 104, 106 and 108 are aligned with associated portions of the controller 102. In one specific example, the stack can include a logic chip 102, two DRAM chips 104 and 106 and a flash memory chip 108. In other examples, other combinations of chips can be used.

In another aspect, the layout of the through-vias in each of the control areas 14x can be specified such that the section of the controller 102 specific to that area 14x can connect to all the chips in the stack associated with the section 14x. This connection can be made with deep silicon vias provided in that section of each chip. The vias for that control area 14x become through chip connections when they pass through a different type of chip.

To explain in the context of a specific example, it can be assumed that controller 102 is a memory controller, chips 104 and 106 are DRAMs and chip 108 is a flash memory. The control section 14a of each chip will be dedicated to DRAMs and the control section 14c of each chip will be dedicated to flash memory. The control section 14b is dedicated to a chip type not being used in this particular design, e.g., an SRAM.

As shown in FIG. 2, the controller 102 includes vias 20 extending from each of the three sections of control area 14. The vias 20 extending from section 14a are coupled to circuitry within the DRAM chips 104 and 106. This connection is illustrated schematically by interconnects 22. Similarly, the vias 20 extending from section 14c are coupled to circuitry within the flash memory chip 108. The vias 20 extending from section 14b are not coupled to any of the chips 102, 104 or 108. The uncoupled vias may (or may not) be grounded or coupled to another supply potential to avoid any adverse effects of having floating conductors.

In other embodiments, some of the through-vias can be common to all device types. For example, a stack enable signal can be used to enable or disable all chips in the stack. As another example, supply voltages such as VDD or ground can be commonly defined and coupled to each chip in the stack.

In a preferred embodiment, the locations of the control area(s) 14 are defined by a pre-set standard, either a de facto standard or a standard promulgated by an organization. In many contexts, the various chip types are produced by a number of manufacturers. A system designer would like to be free to ensure that chips produced by any of the designers would be able to be coupled to a single controller. Accordingly, each of the chips should have all through-vias 20 located in known areas. In a situation where a single manufacturer produces all the chips, a standard may not be needed.

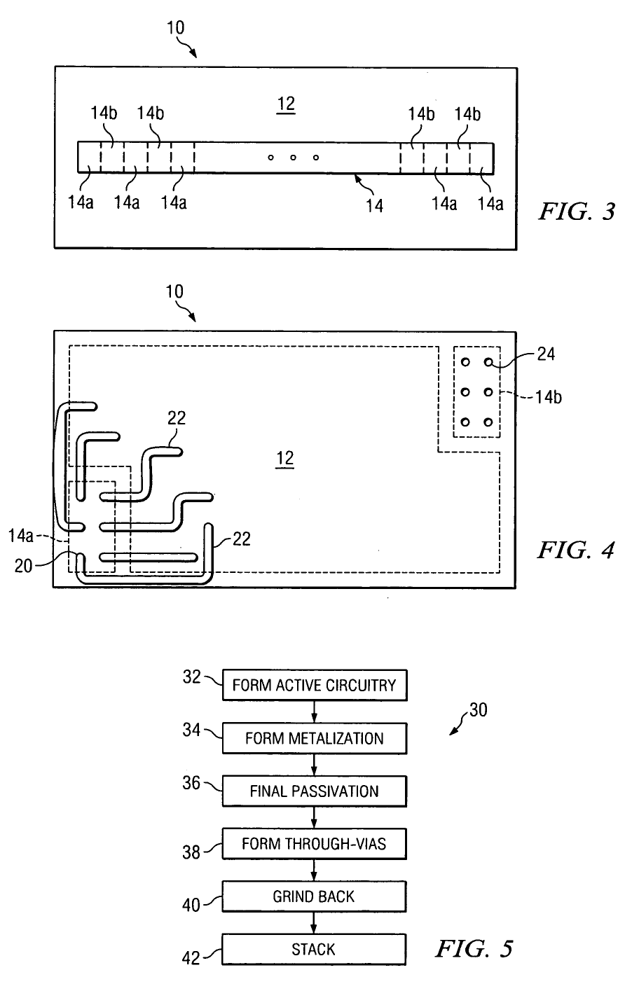

In the example of FIG. 1, the control areas are in the lower right hand corner of the chip. In other examples, the control area 14 can be located in other portions of the chip. FIG. 3 illustrates one such example. In memory circuits, it is common that the bond pads be located in a center region of the chip, e.g., where they can be accessed by memory arrays in upper and lower quadrants of the chip. Accordingly, FIG. 3 illustrates an example where the control area 14 is located in the center region of the chip. In this example, the specific subsections 14a and 14b are interleaved throughout the control area 14. While only two subsections 14a and 14b are shown, it is understood that additional sub-sections can be included. These subsections can be dedicated to different memory types, e.g., DRAM, SRAM, flash, MRAM or others.

In another example, the subsections 14x can be interspersed throughout the chip at pre-defined locations. For example, each subsection 14x can be the size of a via. In another example, one or more subsections 14x can be formed in a ring surrounding the periphery of the chip 10. Other examples are also envisioned.

FIG. 4 illustrates a semiconductor device according to one embodiment of the invention. The chip 10 is formed on a semiconductor substrate. As in the embodiments described above, the chip includes a functional region 12 with integrated circuitry formed therein and control regions 14a and 14b. A number of active through-vias 22 are located within the control area 14a. Each of the active through-vias extends from the upper surface to the lower surface of the semiconductor substrate and is electrically coupled to the integrated circuitry in functional region 12 via interconnects (e.g., metallization) 22.

A number of other through-vias 24 are located in the control area 14b. Each of the other through-vias extends from the upper surface to the lower surface of the semiconductor substrate but is electrically isolated from any integrated circuitry in the substrate. These other through-vias 24 can provide an electrical path from a component above the chip 10 to a component below the chip 10 (even if one or both of these components are not included in a particular application).

In the embodiment illustrated in FIG. 4, section 14a is located in one corner of the chip and section 14b is located in the opposite corner. This configuration was illustrated to provide yet another example. Once again, other locations are envisioned.

The fabrication of a semiconductor chip that can utilize aspects of the present invention will now be described with respect to the flow chart 30 of FIG. 5. As illustrated by box 32, active circuitry is formed at a surface of a semiconductor wafer. This integrated circuitry can include transistors, resistors, capacitors, inductors or other components used to form integrated circuits. For example, active areas that include transistors (e.g., CMOS transistors) can be separated from one another by isolation regions, e.g., shallow trench isolation. This processing can be referred to as front-end or front end of line (FEOL) processing.

As illustrated by box 34, the components formed during the front-end processing can then be interconnected by metallization, sometimes referred to as back end of line (BEOL) processing. Metallization is formed over the active circuitry and in electrical contact with the active circuitry. The metallization and active circuitry together form a completed functional integrated circuit. In other words, the electrical functions of the chip can be performed by the interconnected active circuitry. In a logic chip, the metallization may include many layers, e.g., nine or more, of copper. In other devices, such as DRAMs, the metallization may be aluminum. In other examples, other materials can be used. In fact, the metallization need not actually be metal if other conductors are used.

Referring now to box 36, a final passivation layer is formed over the metallization layer. The final passivation layer can include more than one layer of material, such as silicon oxide, silicon nitride or silicon oxynitride or polyimide, as just a few examples. The final passivation layer includes openings to expose the contact areas.

The formation of the through-vias is illustrated by box 38. A plurality of through-vias can be formed through the semiconductor wafer, i.e., extending from the front-side surface to the back-side surface. The through-vias are electrically coupled as described herein. Optionally, the wafer may be thinned from the back-side, e.g., through grinding, as indicated by box 40. The advantage of thinning the wafer (or chip, if the wafer has already been singulated) is to create a lower profile component, and to shorten the length of the through-vias, which enhances the electric properties and speeds up the via etch processing.

Box 42 is provided to indicate that the completed component can then be stacked with other components. This process can be performed as described above.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A semiconductor device comprising:
a semiconductor substrate having an upper surface and a lower surface opposed to the upper surface;
integrated circuitry formed at the upper surface of the semiconductor substrate;
a plurality of active through-vias, each of the active through-vias being electrically coupled to the integrated circuitry and extending from the upper surface to the lower surface of the semiconductor substrate; and
a plurality of other through-vias, each of the other through-vias extending from the upper surface to the lower surface of the semiconductor substrate and being electrically isolated from any integrated circuitry in the substrate.

2. The device of claim 1, wherein the integrated circuitry comprises memory circuits.

3. The device of claim 2, wherein the integrated circuitry includes at least one array of dynamic random access memory cells.

4. The device of claim 1, wherein the plurality of active through-vias and the plurality of other through-vias are located in a manner determined by a standard.

5. The device of claim 4, wherein the plurality of active through-vias and the plurality of other through-vias are located in a manner determined by a standard promulgated by a standard-setting organization.

6. The device of claim 1, wherein the plurality of active through-vias are located in a center region of the semiconductor substrate.

7. The device of claim 6, wherein the plurality of other through-vias are interleaved between ones of the active through-vias.

8. The device of claim 1, wherein the plurality of active through-vias and the plurality of other through-vias are located in adjacent regions of the semiconductor substrate.

9. The device of claim 8, wherein the plurality of active through-vias and the plurality of other through-vias are located in a corner of the semiconductor substrate.

10. A semiconductor component comprising:
a first semiconductor chip of a first device type, the first semiconductor chip including a first control region with a plurality of active through-vias and a second control region with a plurality of other through-vias, the active through-vias being electrically coupled to integrated circuitry of the first semiconductor chip and the other through-vias being electrically isolated from any integrated circuitry of the first semiconductor chip, the active through-vias and the other through-vias all extending from an upper surface to a lower surface of the first semiconductor chip; and
a second semiconductor chip of a second device type located adjacent the first semiconductor chip, the second device type different than the first device type, the second semiconductor chip including a first control region with a plurality of active through-vias and a second control region with a plurality of other through-vias, the active through-vias being electrically coupled to integrated circuitry of the second semiconductor chip and the other through-vias being electrically isolated from any integrated circuitry of the second semiconductor chip, the active through-vias and the other through-vias all extending from an upper surface to a lower surface of the second semiconductor chip;
wherein ones of the active through-vias of the first semiconductor chip are electrically coupled to ones of the other through-vias of the second semiconductor chip and ones of the active through-vias of the second semiconductor chip are electrically coupled to ones of the other through-vias of the first semiconductor chip.

11. The component of claim 10, further comprising:
a third semiconductor chip of a third device type mounted adjacent the first semiconductor chip, the third device type different than the first device type and the second device type, the third semiconductor chip including a first control region with a plurality of active through-vias and a second control region with a plurality of other through-vias, the active through-vias being electrically coupled to integrated circuitry of the third semiconductor chip and the other through-vias being electrically isolated from any integrated circuitry of the third semiconductor chip, the active through-vias and the other through-vias all extending from an upper surface to a lower surface of the third semiconductor chip;
wherein ones of the active through-vias of the third semiconductor chip are electrically coupled to ones of the other through-vias of the first semiconductor chip and to ones of the other through-vias of the second semiconductor chip.

12. The component of claim 11, wherein the first, the second and the third semiconductor chips all comprise memory chips.

13. The component of claim 10, wherein the first device type is a memory selected from the group consisting of DRAM, flash memory, SRAM and MRAM and wherein the second device type is a memory selected from the group consisting of DRAM, flash memory, SRAM and MRAM.

14. The component of claim 10, further comprising a third semiconductor chip of the first device type mounted to the upper or lower surface of the first semiconductor chip.

15. The component of claim 14, wherein the third semiconductor chip includes a first control region with a plurality of active through-vias and a second control region with a plurality of other through-vias, the active through-vias being electrically coupled to integrated circuitry of the third semiconductor chip and the other through-vias being electrically isolated from any integrated circuitry of the third semiconductor chip, the active through-vias and the other through-vias all extending from an upper surface to a lower surface of the third semiconductor chip;
wherein ones of the active through-vias of the third semiconductor chip are electrically coupled to ones of the active through-vias of the first semiconductor chip and ones of the other through-vias of the third semiconductor chip are electrically coupled to ones of the other through-vias of the first semiconductor chip.

16. The component of claim 10, further comprising a common device electrically coupled to the active through-vias of the first semiconductor chip, the other through-vias of the first semiconductor chip, the active through-vias of the second semiconductor chip, and the other through-vias of the second semiconductor chip.

17. The component of claim 16, wherein the common device comprises a third semiconductor chip.

18. The component of claim 17, wherein the common device is mounted in a stacked arrangement with the first semiconductor chip and the second semiconductor chip.

19. The component of claim 10, wherein the first semiconductor chip includes at least one common through-via and the second semiconductor chip includes at least one common through-via electrically coupled to the common through-via of the first semiconductor chip.

20. A method of making a semiconductor device, the method comprising:
receiving a standard providing location information related to locations of through-vias dedicated to a component of a first device type and to locations of through-vias dedicated to a component of a second device type;
forming integrated circuitry in a semiconductor substrate, the integrated circuitry being connected to perform functions associated with the first device type; and
forming a plurality of active through-vias in the semiconductor substrate, the active though-vias extending from an upper surface of the semiconductor substrate to a lower surface of the semiconductor substrate and being electrically coupled to the integrated circuitry, the active through-vias being located in accordance with the location information related to locations of through-vias dedicated to a component of the first device type.

21. The method of claim 20, further comprising forming a plurality of other through-vias in the semiconductor substrate, the other through-vias extending from an upper surface of the semiconductor substrate to a lower surface of the semiconductor substrate and being electrically isolated from any integrated circuitry in the semiconductor substrate, the other through-vias being located in accordance with the location information related to locations of through-vias dedicated to a component of the second device type.

22. The method of claim 21, further comprising stacking the semiconductor substrate with an other semiconductor substrate so that the active through-vias are electrically coupled to a conductor of the other semiconductor substrate.

23. The method of claim 22, wherein the other through-vias are electrically coupled to integrated circuitry of the other semiconductor substrate.

24. The method of claim 20, further comprising stacking the semiconductor substrate with an other semiconductor substrate so that the active through-vias are electrically coupled to a conductor of the other semiconductor substrate.

25. The method of claim 20, wherein the first device type comprises a dynamic random access memory and wherein the second device type comprises a memory other than a dynamic random access memory.
